(19) United States
(12) Patent Application Publication
(10) Pub. No.: US 2019/0304556 A1
(43) Pub. Date: Oct. 3, 2019

(54) METHOD FOR PROGRAMMING NON-VOLATILE MEMORY AND MEMORY SYSTEM

(71) Applicant: MACRONIX INTERNATIONAL CO., LTD., Hsinchu (TW)

(72) Inventors: Shaw-Hung KU, Hsinchu City (TW); Ta-Wei LIN, Taipei City (TW); Cheng-Hsien CHENG, Yunlin County (TW); Chih-Wei LEE, New Taipei City (TW); Wen-Jer TSAI, Hualien City (TW)

(21) Appl. No.: 15/939,359

(22) Filed: Mar. 29, 2018

(51) Int. Cl. G11C 16/34; G11C 16/10; G11C 16/28; G11C 11/56; G11C 16/04

(52) U.S. Cl. CPC G11C 16/3459; G11C 16/10; G11C 2211/5621; G11C 11/5628; G11C 16/0483; G11C 16/28

(57) ABSTRACT

The method for programming a non-volatile memory includes the following steps. Perform a program and program verify operation for a memory cell in the non-volatile memory, wherein the program and program verify operation includes applying a sequence of incremental step pulses to the memory cell. Perform a post-verifying operation for the memory cell after the memory cell passes the program and program verify operation. Apply a post-programming pulse to the memory cell if the memory cell fails the post-verifying operation, wherein the amplitude of the post-programming pulse is greater than the amplitude of the last pulse in the sequence of incremental step pulses. Perform a read operation to the non-volatile memory to obtain a failed bit count corresponding to the read operation. Adjust a read reference voltage of the read operation to minimize the failed bit count.

### TECHNICAL FIELD

The disclosure relates to a non-volatile memory, especially a method for programming a non-volatile memory and a memory system.

### BACKGROUND

In recent years, non-volatile memories have been commonly used in various electronic devices, such as personal computers, laptop computers, smart phones, tablets, and etc. A non-volatile memory includes an array of memory cells. By adopting Multi-Level-Cell (MLC) technology, more bits can be stored in one memory cell to increase the density of the memory. As the size of the memory cell decreases, the threshold voltage (Vt) margin between different memory states becomes smaller, resulting in higher bit error rate. A noise fluctuation in reading a memory cell may influence the reliability of the memory.

In response to the higher bit error rate, error correcting codes (ECC) have been applied in modern memory devices. For example, ECC techniques include BCH code and Low-density parity-check (LDPC) code. BCH is relatively easy to implement but have difficulty in handling high bit error rate. In contrast, LDPC can afford high bit error rate, but requires larger hardware area, more complicated circuit structure, and more power consumption as well. There is a need to provide a method for programming a non-volatile memory and a memory system such that simple ECC technique can be applied to non-volatile memory devices manufactured in deep nanometer technology nodes.

### SUMMARY OF THE INVENTION

The invention is related to a method for programming a non-volatile memory and a memory system. By applying the multi-times-verify (MTV) and the read-retry (RR) in combination, the failed bit count can be reduced and thus simple ECC can be used in memory devices manufactured in deep nanometer technology nodes.

According to one embodiment of the invention, a method for programming a non-volatile memory is provided. The method includes the following steps. Perform a program and program verify operation for a memory cell in the non-volatile memory, wherein the program and program verify operation includes applying a sequence of incremental step pulses to the memory cell. Perform a post-verifying operation for the memory cell after the memory cell passes the program and program verify operation. Apply a post-programming pulse to the memory cell if the memory cell fails the post-verifying operation, wherein the amplitude of the post-programming pulse is greater than the amplitude of the last pulse in the sequence of incremental step pulses. Perform a read operation to the non-volatile memory to obtain a failed bit count corresponding to the read operation. Adjust a read reference voltage of the read operation to minimize the failed bit count.

According to another embodiment of the invention, a memory system is provided. The memory system includes a non-volatile memory and a controller. The controller is configured to perform a program and program verify operation for a memory cell in the non-volatile memory, perform a post-verifying operation for the memory cell after the memory cell passes the program and program verify operation, apply a post-programming pulse to the memory cell if the memory cell fails the post-verifying operation, perform a read operation to the non-volatile memory to obtain a failed bit count corresponding to the read operation, and adjust a read reference voltage of the read operation to minimize the failed bit count. The controller is configured to apply a sequence of incremental step pulses to the memory cell in the program and program verify operation. The amplitude of the post-programming pulse is greater than the amplitude of the last pulse in the sequence of incremental step pulses.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a diagram illustrating a distribution of threshold voltages (Vt) for multi-level cells (MLC) according to one embodiment of the disclosure.

FIG. 2 shows a block diagram of a memory system according to one embodiment of the disclosure.

FIG. 3 shows a flowchart of a method for programming a non-volatile memory according to one embodiment of the disclosure.

FIG. 4 shows a flowchart of a method for multi-times-verify and read-retry according to one embodiment of the disclosure.

FIG. 5A shows a diagram illustrating a Vt distribution after one P/E cycle according to one embodiment of the disclosure.

FIG. 5B shows a diagram illustrating a Vt distribution after 3000 P/E cycles according to one embodiment of the disclosure.

FIG. 6 shows the relationship between the failed bit count and ΔVp according to one embodiment of the disclosure.

FIG. 7A shows a diagram illustrating a Vt distribution before executing the method for programming the non-volatile memory according to one embodiment of the disclosure.

FIG. 7B shows a diagram illustrating a Vt distribution after executing the method for programming the non-volatile memory according to one embodiment of the disclosure.

FIG. 8 shows a diagram illustrating an improved window for ECC according to one embodiment of the disclosure.

FIG. 9 shows a diagram illustrating the relationship between the program throughput and the number of verify times in the MTV according to one embodiment of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION OF THE INVENTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

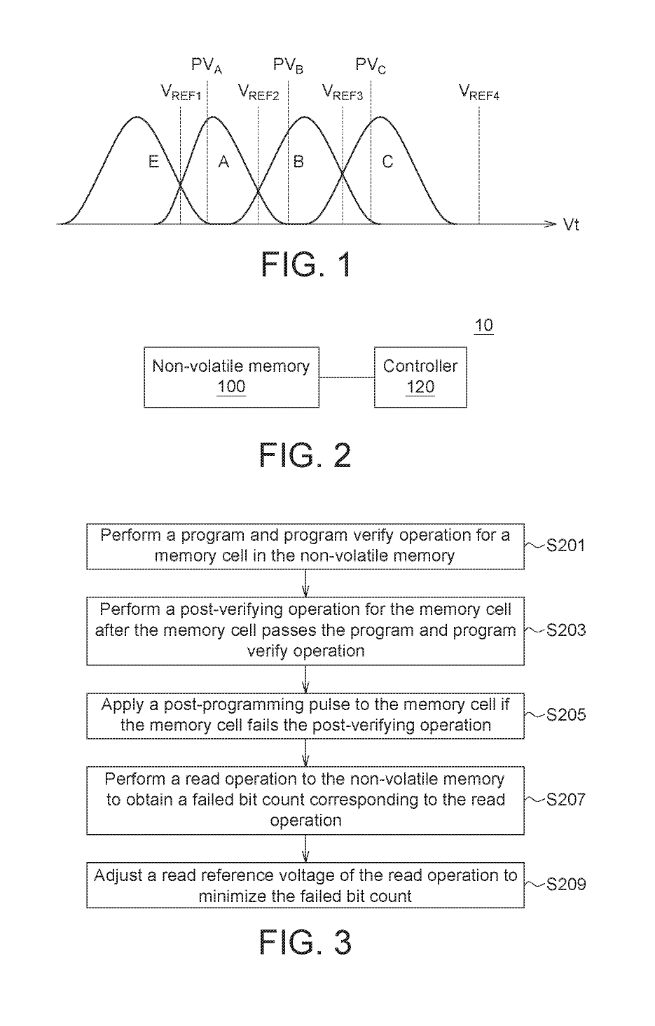

FIG. 1 shows a diagram illustrating a distribution of threshold voltages (Vt) for multi-level cells (MLC) according to one embodiment of the disclosure. In this example, each memory cell of a non-volatile memory array stores 2-bit data. Each MLC has four logical states, namely “11”, “10”, “00”, and “01”, represented as state “E”, “A”, “B”, and “C” in FIG. 1A. The read reference voltage V_{REF1}, V_{REF2}, V_{REF3} may be used to distinguish the memory cells in the states “E”, “A”, “B”, and “C”. The program verify voltage PV_{A}, PV_{B}, PV_{C} may be used to verify whether the cell has been successfully programmed to the states “A”, “B”, “C”, respectively. Note that MLC is used as an example here, however the invention is not limited thereto. The programming method and memory system described in this disclosure may also be applied to other memory devices including triple-level cells (TLC) and quad-level cells (QLC) for example, which can store 3 and 4 bits per cell respectively.

Because of random telegraph noise (RTN) of memory cells, the cell Vt distribution of state “A” has a “tail” portion lower than the program verify voltage PV_{A}. Likewise, the cell Vt distributions of states “B” and “C” also have “tail” portions lower than the program verify voltages PV_{B} and PV_{C} respectively. Such “tail” portions of the cell Vt distributions will narrow down the windows between different memory states, resulting in higher failed bit count (FBC) in the read operation.

FIG. 2 shows a block diagram of a memory system according to one embodiment of the disclosure. The memory system 10 includes a non-volatile memory 100 and a controller 120. The controller 120 is configured to perform a program and program verify operation for a memory cell in the non-volatile memory 100, perform a post-verifying operation for the memory cell after the memory cell passes the program and program verify operation, apply a post-programming pulse to the memory cell if the memory cell fails the post-verifying operation, perform a read operation to the non-volatile memory to obtain a failed bit count corresponding to the read operation, and adjust a read reference voltage of the read operation to minimize the failed bit count. The controller 120 is configured to apply a sequence of incremental step pulses to the memory cell in the program and program verify operation. The amplitude of the post-programming pulse is greater than the amplitude of the last pulse in the sequence of incremental step pulses.

The non-volatile memory 100 retains its information when the power is turned off. The non-volatile memory 100 may include multiple memory blocks, and each memory block may include multiple memory pages. The non-volatile memory 100 is for example a read-only memory (ROM), programmable read-only memory (PROM), electrically alterable read-only memory (EAROM), erasable programmable read-only memory (EPROM), electrically erasable programmable read-only memory (EEPROM), one-time programmable (OTP) memory, multiple-times programmable (MTP) memory, 2D flash memory, or 3D flash memory. The controller 120 may be implemented by a chip, a circuit block in a chip, a firmware, a circuit board including a number of electric elements and a number of conductive wires, or a processor with a computer readable medium storing a number of program codes. The controller 120 may be configured to control the program (write) operation, read operation, and erase operation of the non-volatile memory 100.

FIG. 3 shows a flowchart of a method for programming a non-volatile memory according to one embodiment of the disclosure. The method shown in FIG. 3 may be executed by the memory system 10 shown in FIG. 2. The method includes the following steps. Step S201: Perform a program and program verify operation for a memory cell in the non-volatile memory, wherein the program and program verify operation includes applying a sequence of incremental step pulses to the memory cell. Step S203: Perform a post-verifying operation for the memory cell after the memory cell passes the program and program verify operation. Step S205: Apply a post-programming pulse to the memory cell if the memory cell fails the post-verifying operation, wherein the amplitude of the post-programming pulse is greater than the amplitude of the last pulse in the sequence of incremental step pulses. Step S207: Perform a read operation to the non-volatile memory to obtain a failed bit count corresponding to the read operation. Step S209: Adjust a read reference voltage of the read operation to minimize the failed bit count. Detailed description regarding each step in FIG. 3 will be given below.

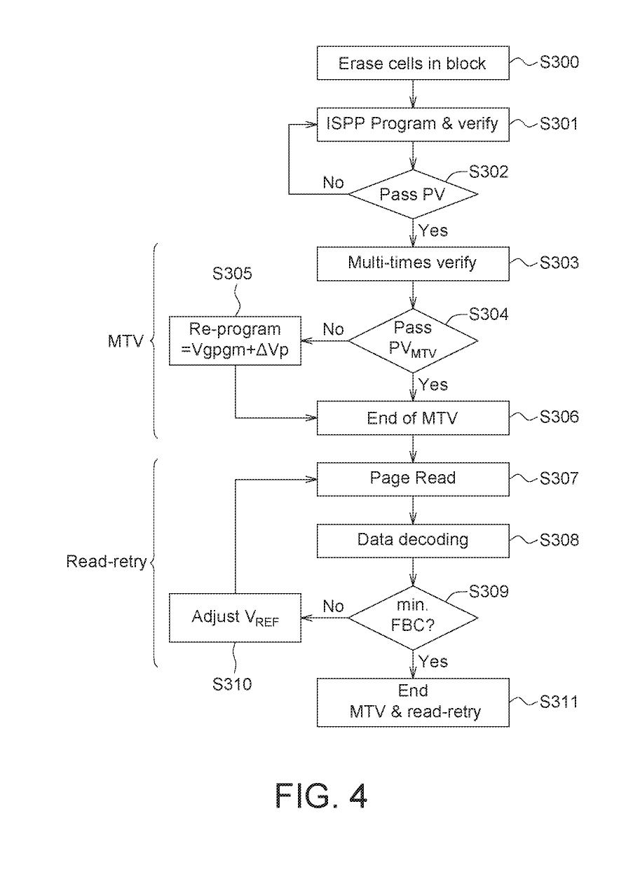

One embodiment of the method in FIG. 3 may be referred to FIG. 4, which shows a flowchart of a method for multi-times-verify and read retry according to one embodiment of the disclosure. In step S300, the controller 120 is configured to erase memory cells in a memory block. Steps S301 and S302 are corresponding to the step S201 in FIG. 3. In step S201: the controller 120 is configured to apply a sequence of incremental step pulses to the memory cell in the non-volatile memory 100. In one embodiment, Incremental Step Pulse Programming (ISPP) technique may be used. The sequence of incremental step pulses has amplitudes increasing with a step size ΔV. For example, the step size ΔV is equal to 0.2V, the step S201 may include program with a 1.0V pulse (S301), verify with a 1.0V pulse (S302), program with a 1.2V pulse (S301), verify with a 1.2V pulse (S302), program with a 1.4V pulse (S301), verify with a 1.4V pulse (S302), and so on, until the memory cell is successfully verified to be programmed to the desired state (passes the step S302).

After the memory cell passes the program and program verify operation in step S302, multi-times verify (MTV) operation is applied to the memory cell in step S303, which is corresponding to the post-verifying operation in step S203 in FIG. 3. In step S304, the controller 120 determines whether the memory cell passes the multi-times verify by applying a post-verify pulse PV_{MTV} to the memory cell. In one embodiment, the post-verifying operation includes multiple post program verify operations. The memory cell fails the post-verifying operation (fails the step S304) if the memory cell fails at least one of the multiple post program verify operations.

If the memory cell fails the post-verifying operation in step S304, proceed to step S305, which is corresponding to the step S205 in FIG. 3. In step S305, the controller 120 is configured to apply a post-programming pulse to the memory cell. The amplitude of the post-programming pulse is greater than the amplitude of the last pulse in the sequence of incremental step pulses in step S301. For example, the amplitude of the last pulse for the memory cell in the ISPP process is Vgpgm=1.4V, then the amplitude of the post-programming pulse is (Vgpgm+ΔVp). Suitable values for ΔVp will be discussed later. By such post-programming operation, Vt of memory cells that fall in the “tail” portion can be increased, resulting in a reduction of the “tail” portion in the Vt distribution.

Proceed to step S306 after performing the post-programming operation in step S305 or if the determination result of step S304 is true. After the MTV operation ends at step S306, a read-retry operation including steps S307 to S310 is then applied to the memory cell. In step S307: the controller 120 is configured to perform a read operation by applying a read reference voltage V_{REF} to the non-volatile memory 100 (for example, reading one memory page at a time). Because the controller 120 knows which state the memory cell in the non-volatile memory 100 has been programmed to, the controller 120 is able to tell whether the memory cell being read is correct or not in step S308. The operation of determining the correctness of the memory cell is represented as data decoding operation in FIG. 4. In addition, the controller 120 calculates the total number of failed bit count (which may be corresponding to the number of faulty memory cells) in step S308. Steps S307 and S308 are corresponding to the step S207 in FIG. 3.

In step S309, the controller 120 determines whether the failed bit count (FBC) obtained in step S308 is a minimum value. If not, proceed to step S310 to adjust the read reference voltage to a different value V_{REF}′. Steps S307 and S308 are executed again with the new read reference voltage V_{REF}′ to obtain a new FBC. The newly obtained FBC is compared with FBC obtained in previous iterations to determine if the minimum FBC has been reached in step S309. Steps S309 and S310 are corresponding to the step S209 in FIG. 3. Steps S307 to S310 may be repeated several times until the minimum FBC has been found, and then step S311 ends the MTV and read-retry operation.

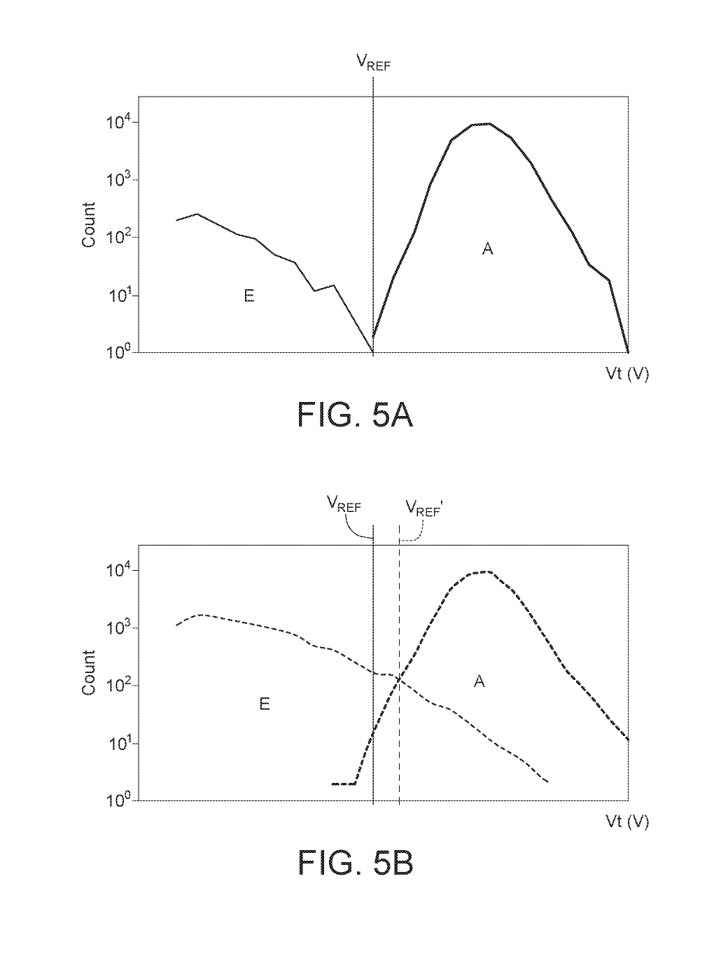

The process of shifting the read reference voltage to minimize the FBC may be referred to in FIG. 5A and FIG. 5B. FIG. 5A shows a diagram illustrating a Vt distribution after one program/erase (P/E) cycle according to one embodiment of the disclosure. An initial read reference voltage V_{REF} shown in FIG. 5A is between the Vt distribution of “E” state and “A” state. FIG. 5B shows a diagram illustrating a Vt distribution after 3000 P/E cycles according to one embodiment of the disclosure. The Vt distribution of “E” state and “A” state clearly changes after 3000 P/E cycles. If the initial read reference voltage V_{REF} is still used in this case, there will be excess failed bits. The steps S307 to S310 seek to obtain an optimized read reference voltage that can minimize the FBC, the FBC including cells in state “E” read as state “A” and cells in state “A” read as state “E”. After several iterations of steps S307 to S310, the read reference voltage V_{REF}′ is found to minimize the FBC, as shown in FIG. 5B.

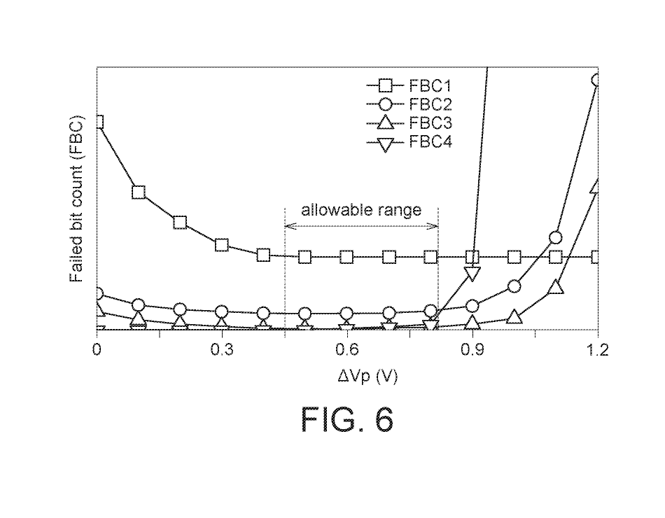

Regarding the suitable values for ΔVp in step S305, FIG. 6 shows the relationship between the failed bit count and ΔVp according to one embodiment of the disclosure. Four curves FBC1, FBC2, FBC3, and FBC4 in FIG. 6 are corresponding to the read reference voltages V_{REF1}, V_{REF2}, V_{REF3}, and V_{REF4} in FIG. 1 respectively. By applying different ΔVp in the post-programming operation, the corresponding failed bit count can be obtained for the four read reference voltages V_{REF1}, V_{REF2}, V_{REF3}, and V_{REF4}. As can be seen in FIG. 6, if ΔVp is too small, Vt of cell in the “tail” portion is not enhanced enough, and thus the lower bound of the Vt distribution for a state does not increase enough, resulting in high FBC. On the other hand, if ΔVp is too large, Vt of some cells may increase too much, making the upper bound of the Vt distribution for a state shift upward, also resulting in excess FBC. Consequently there is an allowable range for ΔVp that keeps the FBC low, as shown in FIG. 6. In one embodiment, ΔVp (representing the difference between the amplitude of the post-programming pulse and the amplitude of the last pulse in the sequence of incremental step pulses) is between 0.5V and 0.9V. In one embodiment, ΔVp is between the step size ΔV used in step S301 (ISPP program and verify operation) and two times the step size 2×ΔV.

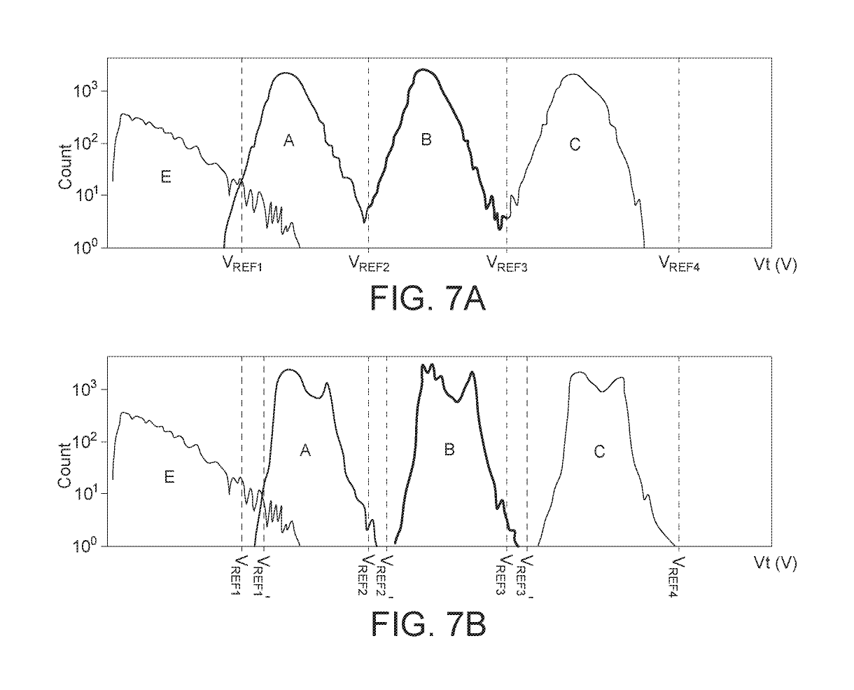

FIG. 7A shows a diagram illustrating a Vt distribution before executing the method for programming the non-volatile memory according to one embodiment of the disclosure. The initial read reference voltages V_{REF1}, V_{REF2}, V_{REF3}, V_{REF4} are shown in FIG. 7A, and Vt in states “A”, “B”, “C” exhibit approximately a bell shaped distribution. FIG. 7B shows a diagram illustrating a Vt distribution after executing the method for programming the non-volatile memory according to one embodiment of the disclosure. By applying the post-programming pulse with appropriate voltage level (ΔVp in the allowable range shown in FIG. 6), the lower bounds of the Vt distribution of states “A”, “B”, “C” are increased (shifted to the right in the figure), while the upper bounds of the Vt distribution of states “A”, “B”, “C” remain nearly the same. As a result, the Vt distribution in states “A”, “B”, “C” is “squeezed” to exhibit a two-hump shaped distribution. The Vt distribution range of states “A”, “B”, “C” becomes narrower, also the distribution curve becomes steeper, effectively reducing the bit error rate. Based on the two-hump shaped distribution, the read reference voltages are shifted to new values V_{REF1}′, V_{REF2}′, V_{REF3}′ to minimize the failed bit count, shown as dashed lines in FIG. 7B. The read reference voltage V_{REF4} does not change in this example for providing sufficient driving capability.

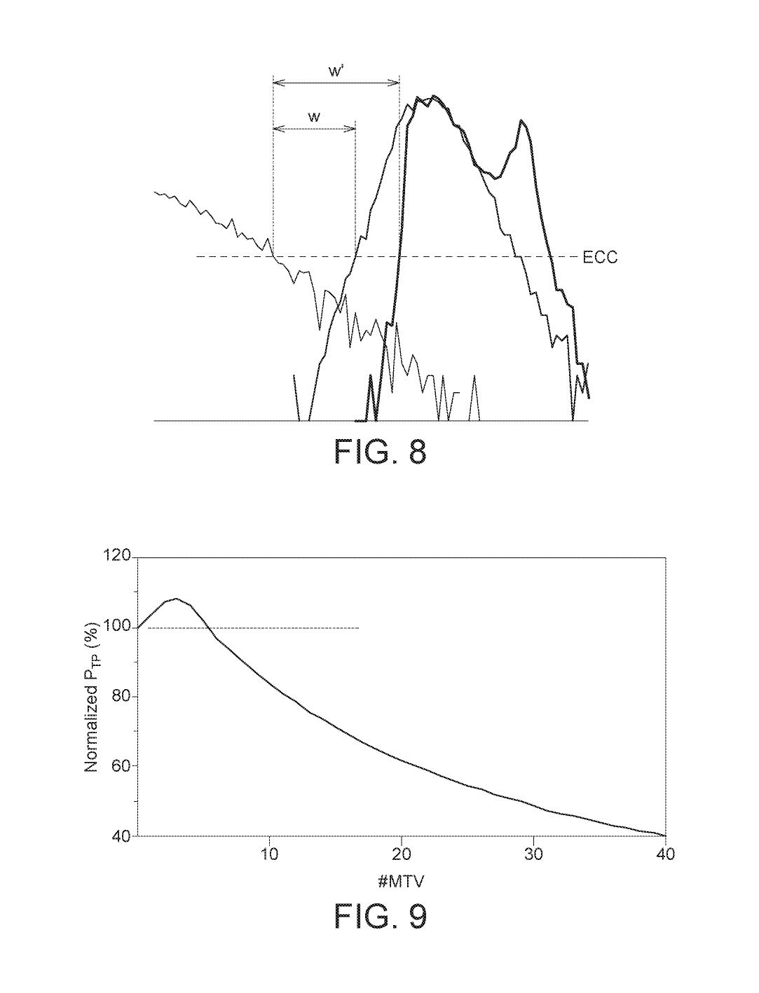

The Vt distribution near the boundary between state “E” and state “A” is enlarged in FIG. 8, which shows a diagram illustrating an improved window for ECC according to one embodiment of the disclosure. The horizontal dashed line ECC represents the ECC capability (the higher the dashed line, the greater the ECC capability). Based on the horizontal line ECC, a region between the high boundary of Vt distribution of state “E” and the low boundary of Vt distribution of state “A” is defined as a reserved window. As can be seen in FIG. 8, the width of the reserved window grows from W to W′ after the MTV and read-retry operation as shown in FIG. 3 or FIG. 4. The increased width of the reserved window makes it possible to apply simple ECC techniques in memory device with small feature size and high density. For example, BCH code (e.g. 20-40 correctible bits in 1 KB data) can be applied in the proposed MTV and read-retry scheme.

FIG. 9 shows a diagram illustrating the relationship between the program throughput and the number of verify times in the MTV according to one embodiment of the disclosure. As described above, the post-verifying operation includes multiple post program verify operations. The number of post program verify operations used in step S203 or S303 is represented as #MTV in FIG. 9. Increasing #MTV in general decreases the program throughput P_{TP} since more time is required for the post-verifying operation. However, by introducing the post-verifying operation, Vt distribution can be tightened effectively, and hence the quality requirement for the ISPP program and verify operation (step S201 or S301) can be relaxed. For example, the step size ΔV used in the ISPP program and verify operation can be increased as compared to convention ISPP process. In one embodiment, the step size ΔV is between 0.2V and 0.6V. Increasing the step size ΔV helps to reduce the time required for the ISPP process. As can be seen in FIG. 9, there is a range for the #MTV that can achieve better program throughput P_{TP}. In other words, a certain amount of additional time is required in the post-verifying operation, but more time is saved in the ISPP process. In one example, the #MTV is set as 2. The step size ΔV without applying MTV technique was originally set as 0.4V, and the average number of required program shots in the ISPP process when ΔV=0.4V was 10. If MTV technique is applied (#MTV=2), the step size ΔV may increase from 0.4V to 0.6V. In one embodiment, the step size ΔV may also be set to an even higher voltage level (possibly higher than 0.6V). The average number of required program shots in the ISPP process decreases from 10 to 7 when the step size ΔV is set as 0.6V. The time required in the ISPP process is reduced, and therefore the program throughput P_{TP} can be improved when the #MTV is set as 2.

According to the embodiments in this disclosure, multi-times-verify and read-retry operations are used in combination for memory cells in the non-volatile memory to change the characteristics of Vt distribution. As a result, the Vt distribution can be tightened to increase the reserved window between different memory states, the effect of noise fluctuation in reading the memory cell can also be reduced, making it possible to apply simple ECC techniques in memory device with small feature size and high density. By applying the proposed technique, the endurance of the memory device can be enhanced. For example, the memory device can remain reliable even after more than 1000 P/E cycles.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for programming a non-volatile memory, the method comprising:
performing a program and program verify operation for a memory cell in the non-volatile memory, wherein the program and program verify operation includes applying a sequence of incremental step pulses to the memory cell;
performing a post-verifying operation for the memory cell after the memory cell passes the program and program verify operation;
applying a post-programming pulse to the memory cell if the memory cell fails the post-verifying operation, wherein an amplitude of the post-programming pulse is greater than an amplitude of the last pulse in the sequence of incremental step pulses;
performing a read operation to the non-volatile memory to obtain a failed bit count corresponding to the read operation; and
adjusting a read reference voltage of the read operation to minimize the failed bit count.

2. The method for programming the non-volatile memory according to claim 1, wherein a difference between the amplitude of the post-programming pulse and the amplitude of the last pulse in the sequence of incremental step pulses is between 0.5V and 0.9V.

3. The method for programming the non-volatile memory according to claim 1, wherein the sequence of incremental step pulses has amplitudes increasing with a step size, and a difference between the amplitude of the post-programming pulse and the amplitude of the last pulse in the sequence of incremental step pulses is between the step size and two times the step size.

4. The method for programming the non-volatile memory according to claim 3, wherein the step size is between 0.2V and 0.6V.

5. The method for programming the non-volatile memory according to claim 1, wherein the post-verifying operation for the memory cell includes a plurality of post program verify operations, and the memory cell fails the post-verifying operation if the memory cell fails at least one of the plurality of post program verify operations.

6. A memory system, comprising:
a non-volatile memory; and
a controller, configured to perform a program and program verify operation for a memory cell in the non-volatile memory, perform a post-verifying operation for the memory cell after the memory cell passes the program and program verify operation, apply a post-programming pulse to the memory cell if the memory cell fails the post-verifying operation, perform a read operation to the non-volatile memory to obtain a failed bit count corresponding to the read operation, and adjust a read reference voltage of the read operation to minimize the failed bit count;
wherein the controller is configured to apply a sequence of incremental step pulses to the memory cell in the program and program verify operation, and an amplitude of the post-programming pulse is greater than an amplitude of the last pulse in the sequence of incremental step pulses.

7. The memory system according to claim 6, wherein a difference between the amplitude of the post-programming pulse and the amplitude of the last pulse in the sequence of incremental step pulses is between 0.5V and 0.9V.

8. The memory system according to claim 6, wherein the sequence of incremental step pulses has amplitudes increasing with a step size, and a difference between the amplitude of the post-programming pulse and the amplitude of the last pulse in the sequence of incremental step pulses is between the step size and two times the step size.

9. The memory system according to claim 8, wherein the step size is between 0.2V and 0.6V.

10. The memory system according to claim 1, wherein the post-verifying operation for the memory cell includes a plurality of post program verify operations, and the memory cell fails the post-verifying operation if the memory cell fails at least one of the plurality of post program verify operations.
